(19) United States
(12) Patent Application Publication
(10) Pub. No.: US 2008/0258150 A1
(43) Pub. Date: Oct. 23, 2008

(54) METHOD TO FABRICATE III-N FIELD EFFECT TRANSISTORS USING ION IMPLANTATION WITH REDUCED DOPANT ACTIVATION AND DAMAGE RECOVERY TEMPERATURE

(75) Inventors: Lee S. McCarthy, Santa Barbara, CA (US); Umesh K. Mishra, Montecito, CA (US); Felix Recht, Isla Vista, CA (US); Tomas Apostol Palacios Gutierrez, Cambridge, MA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/045,561

(22) Filed: Mar. 10, 2008

Related U.S. Application Data
(60) Provisional application No. 60/894,124, filed on Mar. 9, 2007.

(51) Int. Cl. H01L 29/778; H01L 21/338; H01L 21/263

(52) U.S. Cl. 257/76; 438/172; 438/795; 257/E29.246; 257/E21.403; 257/E21.333

(57) ABSTRACT

Structures to reduce dopant activation temperatures for ion implantation in III-N transistors, using low aluminum content layers in proximity to the conducting channel, are disclosed. A method to increase the temperature at which structures can be annealed by annealing in an active nitrogen ambient, for example, in NH₃ in a metalorganic chemical vapor deposition (MOCVD) chamber, is also disclosed.

### CROSS-REFERENCE TO RELATED APPLICATIONS

This application claims the benefit under 35 U.S.C. Section 119(e) of the following co-pending and commonly-assigned U.S. patent application:

U.S. Provisional Patent Application Ser. No. 60/894,124, filed on Mar. 9, 2007, by Lee S. McCarthy, Umesh K. Mishra, Felix Recht, and Tomas A. Palacios Gutierrez, entitled “METHOD TO FABRICATE III-N FIELD EFFECT TRANSISTORS USING ION IMPLANTATION WITH REDUCED DOPANT ACTIVATION AND DAMAGE RECOVERY TEMPERATURE,” attorneys' docket number 30794.226-US-P1 (2006-518-1);

which application is incorporated by reference herein.

This application is related to the following co-pending and commonly-assigned applications:

U.S. Utility patent application Ser. No. 10/962,911, filed on Oct. 12, 2004, by Likun Shen, Sten J. Heikman and Umesh K. Mishra, entitled “GaN/AlGaN/GaN DISPERSION-FREE HIGH ELECTRON MOBILITY TRANSISTORS,” attorneys docket number 30794.107-US-U1, (2003-177), which application claims the benefit under 35 U.S.C Section 119(e) of U.S. Provisional Patent Application Ser. No. 60/510,695, filed on Oct. 10, 2003, by Likun Shen, Sten J. Heikman and Umesh K. Mishra, entitled “GaN/AlGaN/GaN DISPERSION-FREE HIGH ELECTRON MOBILITY TRANSISTORS,” attorneys docket number 30794.107-US-P1 (2003-177);

U.S. Utility patent application Ser. No. 11/523,286, filed on Sep. 18, 2006, by Siddharth Rajan, Chang Soo Suh, James S. Speck, and Umesh K. Mishra, entitled “N-POLAR ALUMINUM GALLIUM NITRIDE/GALLIUM NITRIDE ENHANCEMENT-MODE FIELD EFFECT TRANSISTOR,” attorney's docket number 30794.148-US-U1 (2006-107-2), which claims priority to U.S. Provisional Patent Application Ser. No. 60/717,996, filed on Sep. 16, 2005, by Siddharth Rajan, Chang Soo Suh, James S. Speck, and Umesh K. Mishra, entitled “N-POLAR ALUMINUM GALLIUM NITRIDE/GALLIUM NITRIDE ENHANCEMENT-MODE FIELD EFFECT TRANSISTOR,” attorney's docket number 30794.148-US-P1 (2006-107-1);

U.S. Utility patent application Ser. No. 11/599,874, filed Nov. 15, 2006, by Tomas Palacios, Likun Shen and Umesh K. Mishra, entitled “FLUORINE TREATMENT TO SHAPE THE ELECTRIC FIELD IN ELECTRON DEVICES, PASSIVATE DISLOCATIONS AND POINT DEFECTS, AND ENHANCE THE LUMINESCENCE EFFICIENCY OF OPTICAL DEVICES,” attorneys' docket number 30794.157-US-U1 (2006-129); which application claims the benefit under 35 U.S.C Section 119(e) of U.S. Provisional Patent Application Ser. No. 60/736,628, filed on Nov. 15, 2005, by Tomas Palacios, Likun Shen and Umesh K. Mishra, entitled “FLUORINE TREATMENT TO SHAPE THE ELECTRIC FIELD IN ELECTRON DEVICES, PASSIVATE DISLOCATIONS AND POINT DEFECTS, AND ENHANCE THE LUMINESCENCE EFFICIENCY OF OPTICAL DEVICES,” attorneys' docket number 30794.157-US-P1 (2006-129);

U.S. Utility patent application Ser. No. 11/768,105, filed on Jun. 25, 2007, by Michael Grundmann and Umesh K. Mishra, entitled “POLARIZATION-INDUCED TUNNEL JUNCTION,” attorneys docket number 30794.186-US-U1, (2006-668), which application claims the benefit under 35 U.S.C Section 119(e) of U.S. Provisional Patent Application Ser. No. 60/815,944, filed on Jun. 23, 2006, by Michael Grundmann and Umesh K. Mishra, entitled “POLARIZATION-INDUCED TUNNEL JUNCTION,” attorney's docket number 30794.186-US-P1 (2006-668); and

U.S. Utility patent application Ser. No. 11/841,476, filed on Aug. 20, 2007, by Chang Soo Suh, Yuvaraj Dora, and Umesh K. Mishra, entitled “HIGH BREAKDOWN ENHANCEMENT MODE GALLIUM NITRIDE BASED HIGH ELECTRON MOBILITY TRANSISTORS WITH INTEGRATED SLANT FIELD PLATE,” attorneys docket number 30794.193-US-U1, (2006-730), which application claims the benefit under 35 U.S.C Section 119(e) of U.S. Provisional Patent Application Ser. No. 60/822,886 filed on Aug. 18, 2006, by Chang Soo Suh, Yuvaraj Dora, and Umesh K. Mishra, entitled “HIGH BREAKDOWN ENHANCEMENT MODE GaN-BASED HEMTs WITH INTEGRATED SLANT FIELD PLATE,” attorney's docket number 30794.193-US-P1 (2006-730);

all of which applications are incorporated by reference herein.

### STATEMENT REGARDING FEDERALLY SPONSORED RESEARCH AND DEVELOPMENT

This invention was made with Government support under Grant No. N00014-04-1-0135, awarded by the Office of Naval Research. The Government has certain rights in this invention.

### BACKGROUND OF THE INVENTION

1. Field of the Invention

This invention is related to improved Group-III nitride transistor devices and methods to fabricate same.

2. Description of the Related Art

Ion implantation is the most common method to form doped regions in semiconductors. However, ion implantation has not been used extensively in devices made from Group-III nitride semiconductor materials (also known as “III-nitride,” “III-N” or “nitride” semiconductor materials), such as gallium nitride (GaN), aluminum nitride (AlN), aluminum gallium nitride (AlGaN), indium gallium nitride (InGaN), aluminum indium nitride (AlInN), etc., because of the high temperatures that are typically required to activate dopants, and the capping technology which is then necessary to protect device surfaces.

FIG. 1 is a schematic of an AlGaN/GaN high electron mobility transistor (HEMT) fabricated using present techniques. A HEMT is a field effect transistor (FET) with a junction between two materials with different band gaps (i.e., a heterojunction) as the channel instead of an n-doped region.

The HEMT 10 of FIG. 1 includes an SiC substrate 12, Fe-doped GaN (GaN:Fe) layer 14, two-dimensional electron gas (2DEG) channel 16, AlGan layer 18, source 20, drain 22, gate 24, and SiNₓ passivation layer 26.

Currently, ohmic contacts 20, 22 to AlGaN/GaN HEMTs 10 are formed by depositing metals such as titanium, aluminum, nickel, and gold, which are then annealed at high temperatures (between 600° C. and 1000° C.). The alloy of the metals is critical to the formation of ohmic contacts 20, 22 in this system. The ohmic contacts 20, 22 that are formed tend to have a rough morphology, and rough edges, which can be mitigated to some extent, but is not as smooth as the metals are before the anneal.

The ohmic contact 20, 22 resistance typically depends on the surface preparation before ohmic contact 20, 22 deposition, the composition of the metal stack, including the choice of metals, and the thickness and order in which they are deposited, as well as the temperature of the alloying anneal step. Because this anneal step is near the decomposition temperature of GaN, it must be a short anneal, and may still cause damage to the AlGaN 18 surface if the process is not carefully controlled.

Also, the current process requires that the ohmic contacts 20, 22 be deposited before surface passivation 26 or gate 24 metallization, reducing flexibility in the process design. The need to align the gate 24 metal to the source 20 metal edge is a disadvantage because lithography in the proximity of metals tends to perturb the resultant features due to topology changes and reflections of the gate 24 exposure area off the source 22 metal. This limits the source-gate 22, 24 spacing, making it a critical design rule. If the spacing is too close, the device may short, while if too long, the device may have increased contact resistance. This is further complicated by multi-finger devices, where an excess in gate-source 24, 22 spacing on one finger results in a deficit in spacing on the next finger.

An added concern with current devices is that the alloyed contacts 20, 22 may form spikes which penetrate the AlGaN layer 18, which results in increased buffer leakage currents. Ohmic contacts 20, 22 that did not rely on spiking through the AlGaN layer 18, or where the spikes are screened by Si doping, will prevent excess leakage through these buffer layers 18.

Thus, there is a need in the art for improved techniques of ion implantation for III-nitride semiconductor materials. The present invention satisfies this need.

### SUMMARY OF THE INVENTION

To overcome the limitations in the prior art described above, and to overcome other limitations that will become apparent upon reading and understanding the present specification, the present invention describes structures to reduce dopant activation temperatures for ion implantation in III-N transistors, such as HEMTs, metal epitaxial semiconductor field effect transistors (MESFETs), heterojunction bipolar transistors (HBTs), and optical devices such as lasers and light emitting diodes (LEDs). A method to increase the temperature at which structures can be annealed by annealing in an active nitrogen ambient, for example, in NH₃ in a metalorganic chemical vapor deposition (MOCVD) chamber, is also described.

### BRIEF DESCRIPTION OF THE DRAWINGS

Referring now to the drawings in which like reference numbers represent corresponding parts throughout:

FIG. 1 is a schematic of an AlGaN/GaN HEMT.

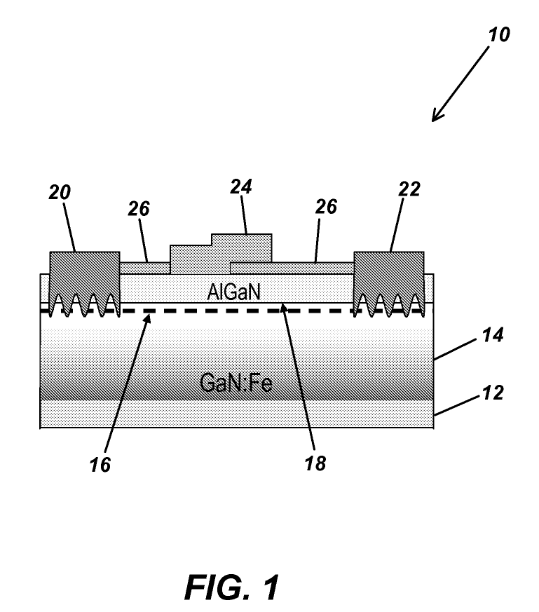

FIG. 2 is a schematic of an ion implanted Ga-face AlGaN/GaN HEMT.

FIG. 3 is a schematic of an ion implanted N-face AlGaN/GaN HEMT.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Technical Description

The present invention describes structures where the channel of an AlGaN/GaN HEMT is designed to reduce the barrier to current flow from implanted GaN regions to the AlGaN/GaN channel.

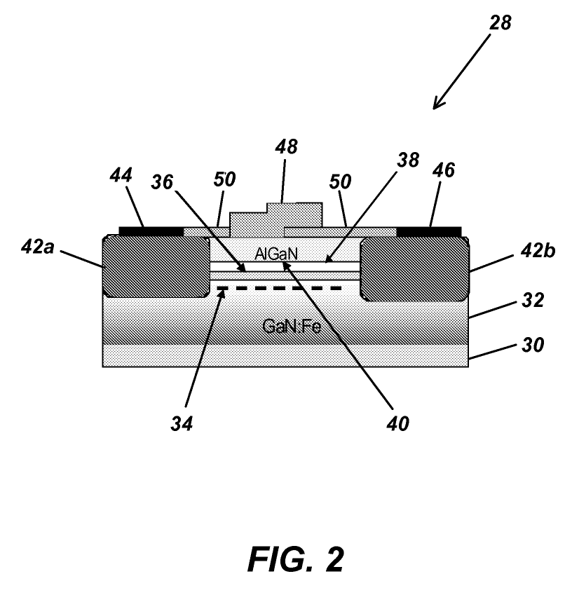

In a first case, illustrated in the schematic of FIG. 2, the use of ion implantation in conjunction with a GaN spacer HEMT 28 is proposed. The ion implanted gallium-face (Ga-face) AlGaN/GaN HEMT 28 of FIG. 2 includes an SiC substrate 30, a GaN:Fe layer 32, a GaN 2DEG channel 34, an Al(In)N interlayer or barrier layer 36, a GaN spacer layer 38, a GaN or GaN/AlGaN layer 40, an ion-implanted Si-doped GaN source region 42a contacting the GaN channel 34, an ion-implanted Si-doped GaN drain region 42b contacting the GaN channel 34, a source contact 44, a drain contact 46, a gate 48 positioned between the source 44 and drain 46, and an SiNₓ passivation layer 50.

The HEMT 28 is grown in the (+)ve C plane direction, where a buffer layer 32 is followed by a GaN channel 34 (with or without an InGaN or other confinement back barrier), and this is followed by a thin Al(In)N barrier layer 36, a GaN spacer layer 38, and then either GaN or composite GaN/AlGaN layers 40. The Al(In)N or GaN/AlGaN layers 36, 40 may also include indium (In).

This structure 28 has the special attribute that the channel 34 is separated from an adjacent GaN layer 38 by only a thin (several Angstroms) Al(In)N barrier layer 36, because activation and implantation damage recovery in GaN can be accomplished at a lower temperature than can be accomplished in the GaN/AlGaN layers 40. Depositing low Al-content layers 36 in proximity to a conducting channel 34 of the III-N transistor 28 reduces dopant activation temperatures for ion implantation. The GaN spacer HEMT 28 may be contacted more easily with dopants activated at lower temperatures than devices where the GaN/AlGaN layer 40 directly contacts the channel 34. Also, a self aligned HEMT may be designed such that the gate slightly overlaps at least the source and possibly the drain contacts, possibly with a thin AlGaN gating layer or an insulating layer such as an oxide or other dielectric layer. Finally, this device 28 can be designed to be an enhancement mode device.

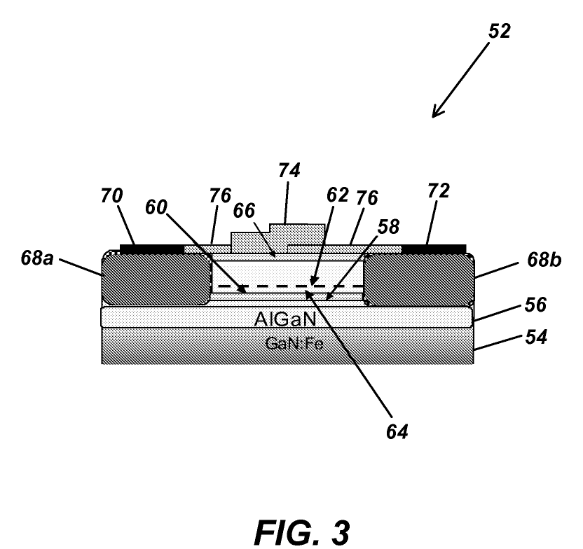

Also, the present invention proposes devices (including the GaN spacer device) in nitrogen-face (N-face) material, as shown in the schematic of FIG. 3. The ion implanted N-face AlGaN/GaN HEMT 52 of FIG. 3, with the substrate removed, includes a GaN:Fe layer 54, an AlGaN layer 56, a GaN spacer layer 58, an Al(In)N interlayer or barrier layer 60, a GaN 2DEG channel 62, a GaN spacer layer 64, an AlN gate layer 66, an ion-implanted Si-doped GaN source region 68a contacting the GaN channel 62, an ion-implanted Si-doped GaN drain region 68b contacting the GaN channel 62, a source contact 70, a drain contact 72, a gate 74 positioned between the source 70 and drain 72, and an SiNₓ passivation layer 76.

In the (−) C-crystal direction, the AlGaN layer 56 is below the channel 62 (due to the reversed polarization charges), and dopants can be implanted from the (−) C direction, so that they do not pass through the AlGaN layers 56 that are providing polarization doping for the HEMT 52.

In this case, low temperature activation can be used to provide high conductivity implanted regions 68 without damaging the underlying layers. The low temperature activation method uses an anneal with an ammonia or other active nitrogen source to provide an overpressure of active nitrogen, to prevent the decomposition or other damage to the III-N surface. Annealing the ohmic contacts in an active nitrogen ambient increases the temperature at which the ohmic contacts for a III-nitride semiconductor device can be annealed. In this fashion, the device 52 structure can be annealed at temperatures above the normal decomposition temperature of GaN or AlGaN, without damaging the device 52 structure. Additionally, the annealing the III-nitride HEMT 52 in active nitrogen environment has resulted in reduced leakage currents, reduced dispersion after passivation, and increased power performance and efficiency.

For example, III-N HEMTs with aluminum compositions of 22% have been annealed by MOCVD with a thermocouple temperature of 1260° C., where the same anneal in N₂ may cause decomposition of the III-N surface. Although the surface temperature of the III-N in this chamber is likely to be 100° C. cooler than the thermocouple temperature, it is possible that even higher temperatures could be used without damage in an ammonia ambient, or that the use of higher Al content in the top layer of the structure could lead to higher thermal stability of the device. At these temperatures, with an ion implant dose of 1×10¹⁶ cm⁻³, contacts to underlying implanted GaN have yielded contact resistances below 0.1 Ωmm, and sheet resistances of 100 Ω/square. With further effort, the performance for implanted contacts will likely be improved.

In addition, ion implantation for the ion implanted source or drain regions 68 may be angled. The use of angled implants 68 has shown significant reductions in resistance from the implanted region 68 to the 2DEG channel 62 in the HEMT structure 52. The angle of implant relative to the surface normal has an effect on both the lateral resistance of the implanted region 68 in the HEMT structure 52, and the on the resistance between the implanted region 68 and the 2DEG in channel 62. Various angles of implant, or a combination of angles, can be used to minimize the total resistance between the contacts 70, 72 and the 2DEG in channel 62. Consecutive implants at +/−40 degrees have resulted in a total contact 70, 72 resistance to the 2DEG of 0.2 Ohm-mm a significant reduction relative to lesser angles. Further optimization of the implant angle, the number of implants, and the implant energies and species used is expected to result in further reduction in contact 70, 72 resistance.

Possible Modifications and Extensions

The discussion above describes a preferred embodiment of the present invention. However, many alternatives, extensions and variations are possible, for example:

a. A device like the one described above, where, in the case of the Ga-face device, an InGaN back barrier is used to increase confinement.

b. A device like the one described above, where the barrier layer or layers contain at least one Group-III element and nitrogen, and the underlying channel layer or layers contain at least one Group-III element and nitrogen.

c. A device like the one described above, where the charge in the channel region is provided by polarization charge induced by compositionally grading a III-N layer.

d. A device like the one described above, where the charge in the channel is induced due to the presence of polarization dipoles which are created by the straining of a III-N layer or layers.

e. A device like the one described above, where instead of a GaN spacer, InGaN or other III-N material is used as a spacer layer.

f. A device like the one described above, where, in both the Ga-face and the N-face embodiments, the thickness of the GaN spacer layer goes to zero.

g. A device like the one described above, where the shape of the gate differs, for example, a sub-micron “T” gate.

h. A device like the one described above, where deep implants are used under the Si implant to reduce sub-threshold leakage or to shape the electric field.

i. A device like the one described above, with differing III-N alloy compositions, including schemes where the surface layer has higher Al or In composition than the rest of the barrier layer.

j. A method like the one described above, where the implanted Si is annealed at the same time as the contact layer, either in an active N ambient, or in another ambient with a reduced temperature, for example, 870° C. in nitrogen gas, or in nitrogen+hydrogen gas (forming gas).

k. A method like the one described above, where the implant angle is altered.

l. A method like the one described above, where the implantation is performed with a thin III-N barrier layer, then after the activation anneal, III-N regrowth is performed to grow the remaining barrier, thus resulting in un-damaged III-N over the implanted region, leading to increased polarization induced charge under the channel.

m. A method like the one described above, where the structure is grown in a non-polar or semi-polar direction.

n. A method like the one described above, where other materials such as Te, Mg, C, Be, O, Fe are implanted to provide acceptors or donors.

o. A method like the one described above, where GaN powder or another GaN wafer is used to provide the active nitrogen ambient instead of or in addition to NH₃.

p. A method like the one described above, where AlGaN or AlN layers contain indium, either introduced during growth or by implantation.

q. A method like the one described above, where dopants or other ions are implanted at higher energies to provide a barrier to sub-threshold leakage such as Fe implants under the Si source/drain contact areas.

r. A method like the one described above, where implants are performed with a thin barrier layer such as Al(In)GaN in place, and annealed, then either before or after annealing (or both) more III-N material and/or dielectric material is added. This results in a FET where much of the barrier layer is undamaged, reduced straggle of implanted dopants, and the possibility to fabricate enhancement mode devices (if a dielectric is added that results in a channel which is depleted under zero bias).

s. A method like the one described above, where a heterojunction bipolar transistor is fabricated with implanted regions such as emitter and collector regions in an NPN transistor, or implanted base regions in a PNP transistor. Other species may also be used to provide P-type dopants in these devices.

t. A method like the one described above where implantation is used to increase the conductivity or reduce contact resistance to p-type or n-type layers in LED or laser structures.

Advantages and Improvements Over Existing Practice

This invention describes a method for improving III-N transistors using device structures that reduce the necessary activation and damage recovery temperature associated with implanted dopants. The ability to reduce ohmic contact resistances and access resistances is critical both to the manufacturability and the performance of III-N transistors.

As transistors scale to smaller and smaller dimensions to increase performance, ohmic contact and lateral parasitic access resistances must also scale to take advantage of the shrinking dimensions of the devices. With successful scaling of these devices, they may be able to achieve significant power amplification at frequencies well over 40 GHz.

These high frequency devices, however, will require extremely low access resistances which are not currently available in state-of-the-art devices. The use of ion implantation in III-N materials can lead to extremely low sheet resistances and contact resistances in HEMTs.

Ion implantation with low temperature activation also has an impact on the manufacturability of III-N transistors. The use of ion implantation can reduce gate-source lithography critical dimensions because the gate is aligned to the implanted source region rather than the source metal (which can be offset). This will increase yield and performance in electronic devices.

Also, the use of ion implantation will increase the repeatability and control of contact resistance because implanted contacts don't rely on surface conditions. Ohmic contacts to implanted regions may not (depending on implant conditions) require an alloy anneal, and therefore do not suffer from the rough morphology associated with the high temperature anneals used currently.

In addition, the use of implantation, by removing the need for alloyed contacts makes possible the use of a large number of different metals which could not be used in alloyed contacts. The use of alternative ohmic contact metals creates design flexibility which has not previously existed.

The use of reduced temperature (below 1500° C.) activation techniques, and techniques which do not require capping technology are critical for manufacturable processes.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A III-nitride field effect transistor (FET), comprising:
(a) a gallium nitride (GaN) channel;
(b) a thin aluminum nitride (AlN) or aluminum gallium nitride (AlGaN) layer in proximity to the GaN channel;
(c) one or more barrier layers in proximity to the AlN or AlGaN layer;
(d) an ion implanted source contacting the GaN channel;
(e) a drain contacting the GaN channel; and
(f) a gate positioned between the source and the drain.

2. The III-nitride FET of claim 1, further comprising a nitride spacer layer between the barrier layers and the AlN or AlGaN layer.

3. The III-nitride field effect transistor (FET) of claim 1, wherein the AlN or AlGaN layer also includes indium (In).

4. The III-nitride FET of claim 1, wherein ion implantation for the ion implanted source is angled.

5. A method for reducing dopant activation temperatures for ion implantation in a III-N transistor, comprising:
(a) depositing low aluminum content layers in proximity to a conducting channel of the III-N transistor.

6. A method for increasing a temperature at which ohmic contacts for a III-nitride semiconductor device are annealed, comprising:
(a) annealing the ohmic contacts in an active nitrogen ambient.

7. A method for reducing leakage currents, reducing dispersion after passivation, and increasing power performance and efficiency of a III-nitride high electron mobility transistor (HEMT), comprising:
(a) annealing the HEMT in an active nitrogen environment.
